(19) United States
(12) Patent Application Publication
(10) Pub. No.: US 2009/0166692 A1
(43) Pub. Date: Jul. 2, 2009

(54) CMOS IMAGE SENSOR AND METHOD FOR MANUFACTURING THE SAME

(75) Inventor: Chung Kyung JUNG, Anyang-si (KR)

Correspondence Address: Workman Nydegger;1000 Eagle Gate Tower, 60 East South Temple, Salt Lake City, UT, 84111, US

(73) Assignee: DONGBU HITEK CO., LTD., Seoul (KR)

(21) Appl. No.: 12/262,944

(22) Filed: Oct. 31, 2008

(30) Foreign Application Priority Data
Dec. 28, 2007 (KR) 10-2007-0140310

(51) Int. Cl. H01L 27/146; H01L 31/18

(52) U.S. Cl. 257/292; 438/70; 257/E27.133

(57) ABSTRACT

A CMOS image sensor may include a dielectric layer formed on a semiconductor substrate, first and second passivation layers sequentially formed on the whole surface of the dielectric layer, a planarization layer, a color filter layer, and an overcoating layer and a microlens sequentially formed on the second passivation layer. The CMOS image sensor may further include a plurality of metal pads arranged on the dielectric layer to surround the microlens, a water barrier formed on the dielectric layer between the microlens and the metal pads, and first and second open parts exposing the metal pads and the water barrier.

### CROSS-REFERENCE TO RELATED APPLICATION

This application claims the benefit of the Korean Patent Application No. 10-2007-0140310, filed on Dec. 28, 2007, which is hereby incorporated by reference in its entirety.

### BACKGROUND

1. Field of the Invention

Embodiments of the present invention relate to a complementary metal oxide semiconductor (CMOS) image sensor, and more particularly, to a CMOS image sensor capable of preventing infiltration of water, and a method for manufacturing the same.

2. Discussion of the Related Art

Generally, an image sensor refers to a device that converts an optical signal to an electric signal using photosensitivity of a semiconductor. Image sensors may broadly be classified as either a charge coupled device (CCD) or a complementary metal oxide semiconductor (CMOS) image sensor.

In a CCD, a plurality of photodiodes that convert optical signals to electric signals are arranged in a matrix form. The CCD also comprises a plurality of vertical CCDs (VCCD) disposed between the respective photodiodes arranged in the matrix form to vertically transmit electric charges generated from the photodiodes, a plurality of horizontal CCDs (HCCD) to horizontally transmit the electric charges transmitted by the VCCDs, and a sense amplifier to detect the horizontally transmitted electric charges and thereby output electric signals.

The above-described CCD has a complicated system of operation, consumes a lot of power, and requires multilevel photo processes. Therefore, the manufacturing process of the CCD is also complicated.

Furthermore, the CCD is hard to manufacture in a compact size because it is difficult to integrate a control circuit, a signal processing circuit, an A/D converter circuit, and the like in a CCD chip.

Recently, to this end, the CMOS image sensor has been considered as a next-generation image sensor capable of addressing the shortcomings of the CCD.

According to the CMOS technology that uses a control circuit and a signal processing circuit as peripheral circuits, the CMOS image sensor includes MOS transistors on a semiconductor substrate. The number of MOS transistors corresponds to the number of unit pixels. The CMOS image sensor sequentially detects outputs of the respective unit pixels using the MOS transistors in a switching manner.

For example, the CMOS image sensor is formed with a photodiode and a MOS transistor in each unit pixel. An image is represented by electric signals detected sequentially in the switching manner by each unit pixel.

Thus by applying the CMOS manufacturing technology, a CMOS image sensor can be formed that consumes less power and has a reduced number of photo process, and therefore a more simplified manufacturing process, than a CCD image sensor.

Hereinafter, a manufacturing method for a conventional CMOS image sensor will be explained with reference to the accompanying drawings.

FIGS. 1A through 1D are sectional views illustrating the manufacturing processes of the conventional CMOS image sensor.

First, as shown in FIG. 1A, a dielectric layer 101 such as a gate dielectric layer or an interlayer dielectric is formed on a semiconductor substrate 100. In addition, a metal pad 102 for each signal line is formed on the dielectric layer 101. A first passivation layer 103 comprising an oxide layer or a nitride layer is formed on the whole surface of the dielectric layer 101 including the metal pad 102.

Next, referring to FIG. 1B, a photoconductive layer 104 is applied on the first passivation layer 103, and patterned through exposure and development to expose an upper part of the metal pad 102. For example, an open part 105 is formed at the metal pad 102 by selectively etching the first passivation layer 103 using the patterned photoconductive layer 104.

As shown in FIG. 1C, next, the photoconductive layer 104 is removed, and a second passivation layer 110 is formed on the whole surface of the semiconductor substrate 100. The second passivation layer 110 may be formed by vapor-depositing a thermal resin (TR) or a thin layer of tetraethoxysilane (TEOS) for protecting a microlens 109 formed in a following process. Here, the second passivation layer 110 may be formed using a low temperature oxide (LTO).

As shown in FIG. 1D, a planarization layer 106 is formed by vapor-depositing a silicon nitride layer or a silicon oxide nitride layer on the whole surface of the second passivation layer 110. The planarization layer 106 is selectively etched by a photo process to remain only on parts not corresponding to the metal pad 102. Additionally, a color filter layer 107 is formed on the planarization layer 106 corresponding to respective photodiode regions (not shown). Here, the color filter layer 107 may be formed by applying a corresponding color resist and performing photolithography using a dedicated mask.

After this, an overcoating layer 108 is formed on the whole surface of the substrate 100 which includes the color filter layer 107, and then selectively etched by the photo process to remain only at parts not corresponding to the metal pad 102.

Next, a polymer is bonded to the overcoating layer 108 as a material for the microlens 109. A microlens area is defined by patterning the photoconductive layer by exposure and development. Then, the polymer, which is the microlens material layer, is selectively patterned so that a microlens pattern is formed corresponding to the color filter layer 107. The microlens pattern is thermally processed by a reflow process, thereby forming the microlens 109 of a hemispheric shape having a predetermined curvature.

However, in the conventional CMOS image sensor, because the LTO is vapor-deposited at a low temperature, density of the LTO layer is insufficient. Also, since the LTO layer is porous and hydrophilic, water may easily infiltrate the microlens, thereby causing a crack and deteriorating the lifespan of the microlens. The crack may cause stress during wire bonding of the semiconductor, and accordingly the microlens may even be broken due to the stress.

### SUMMARY OF SOME EXAMPLE EMBODIMENTS

In general, example embodiments of the invention relate to a CMOS image sensor and a manufacturing method for the same that substantially obviate one or more problems due to limitations and disadvantages of the related art.

For example, embodiments of the present invention relate to providing a CMOS image sensor capable of preventing infiltration of water, and a method for manufacturing the same.

According to a first embodiment, a CMOS image sensor comprises a dielectric layer formed on a semiconductor substrate, first and second passivation layers sequentially formed on the whole surface of the dielectric layer, a planarization layer, a color filter layer, and an overcoating layer and a microlens sequentially formed on the second passivation layer. The CMOS image sensor further comprises a plurality of metal pads arranged on the dielectric layer to surround the microlens, a water barrier formed on the dielectric layer between the microlens and the metal pads, and first and second open parts exposing the metal pads and the water barrier.

According to a second embodiment, a method for manufacturing a CMOS image sensor comprises forming a dielectric layer, a metal pad, and a first passivation layer sequentially on the whole surface of a semiconductor substrate and forming first and second open parts by selectively etching the first passivation layer. Next, at least one water barrier is formed on the dielectric layer through the second open part and a second passivation layer may be formed on the whole surface of the first passivation layer. The method may also include forming a planarization layer, a color filter layer, an overcoating layer, and a microlens sequentially on a microlens area formed on the second passivation layer.

This Summary is provided to introduce a selection of concepts in a simplified form that are further described below in the Detailed Description. This Summary is not intended to identify key features or essential characteristics of the claimed subject matter, nor is it intended to be used as an aid in determining the scope of the claimed subject matter.

Additional features will be set forth in the description which follows, and in part will be obvious from the description, or may be learned by the practice of the teachings herein. Features of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

Aspects of example embodiments of the invention will become apparent from the following description of example embodiments given in conjunction with the accompanying drawings, in which:

FIGS. 1A to 1D are process sectional views illustrating a method for manufacturing a CMOS image sensor according to a conventional art;

FIG. 2 is a plan view of a CMOS sensor according to an embodiment of the present invention;

FIG. 3 is a sectional view of FIG. 2 cut along a line A-A′; and

FIGS. 4A to 4E are process sectional views showing a method for manufacturing the CMOS image sensor according to the embodiment of FIG. 2.

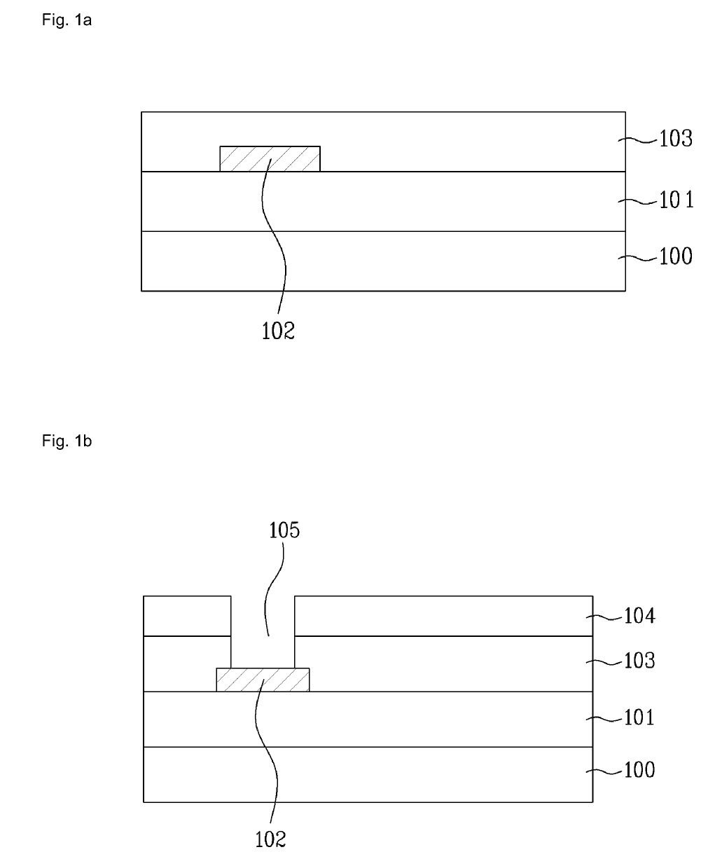

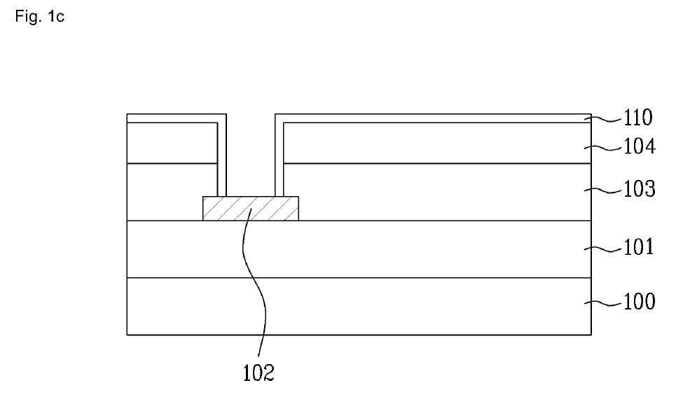

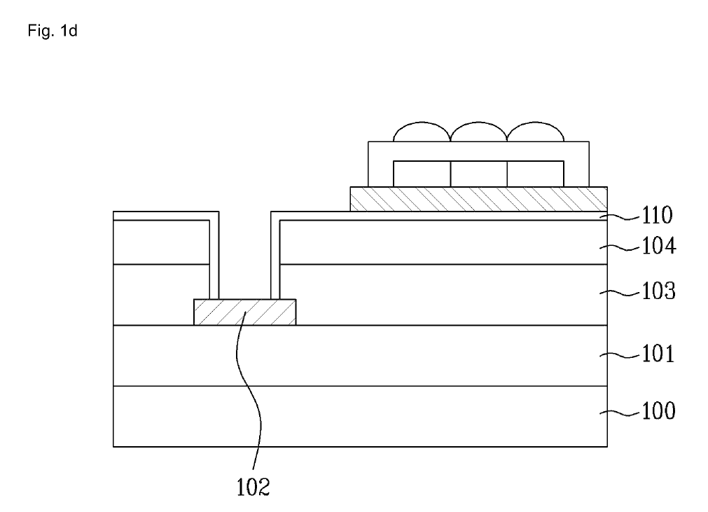

### DETAILED DESCRIPTION OF SOME EXAMPLE EMBODIMENTS

In the following detailed description of the example embodiments, reference is made to the accompanying drawings that show, by way of illustration, specific embodiments of the invention. In the drawings, like numerals describe substantially similar components throughout the several views. These embodiments are described in sufficient detail to enable those skilled in the art to practice the invention. Other embodiments may be utilized and structural, logical and electrical changes may be made without departing from the scope of the present invention. Moreover, it is to be understood that the various embodiments of the invention, although different, are not necessarily mutually exclusive. For example, a particular feature, structure, or characteristic described in one embodiment may be included within other embodiments. The following detailed description is, therefore, not to be taken in a limiting sense, and the scope of the present invention is defined only by the appended claims, along with the full scope of equivalents to which such claims are entitled.

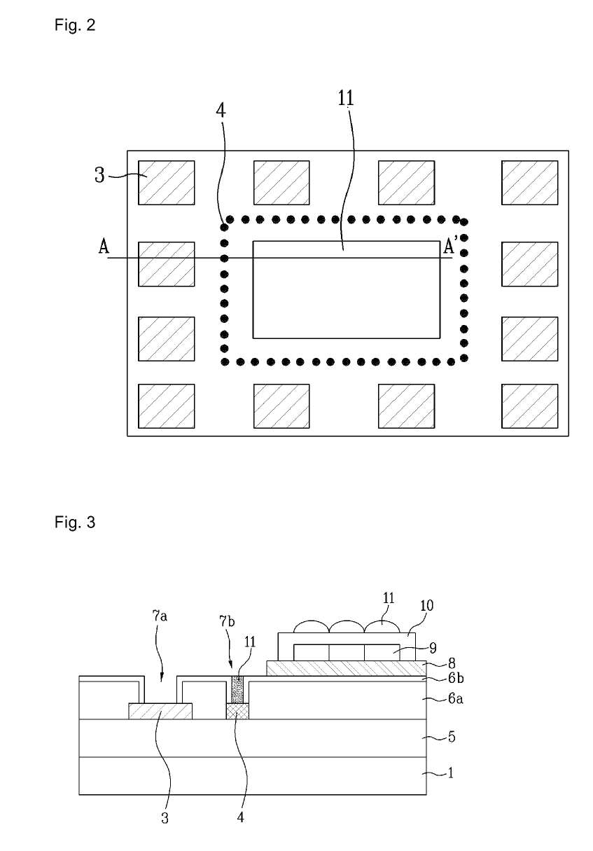

FIG. 2 is a plan view of a CMOS sensor according to an embodiment of the present invention, and FIG. 3 is a sectional view of FIG. 2 cut along a line A-A′.

As shown in FIG. 2 and FIG. 3, the CMOS image sensor comprises a semiconductor substrate 1 and a dielectric layer 5 formed on the semiconductor substrate 1 in the form of a gate dielectric layer or an interlayer dielectric. A plurality of metal pads 3 may be formed on the dielectric layer 5 along an outer edge of the semiconductor substrate 1 to surround a microlens 11 and a plurality of water barriers 4 may be formed on the dielectric layer 5 disposed between the microlens 11 and the metal pads 3. The CMOS image sensor may further comprise a first passivation layer 6a formed of, e.g., an oxide layer or a nitride layer on the whole surface of the dielectric layer 5 and a second passivation layer 6b formed on the first passivation layer 6a. First and second open parts 7a and 7b may be formed on the metal pads 3 and the water barriers 4 by selectively etching the first and the second passivation layers 6a and 6b. A planarization layer 8 may be formed in a microlens area on the second passivation layer 6b, a color filter layer 9 may be formed on the planarization layer 8, and an overcoating layer 10 may be formed on the whole surface of the planarization layer 8 which includes the color filter layer 9. A microlens 11 may then be formed on the overcoating layer 10.

The second passivation layer 6b may be formed using a low temperature oxide (LTO).

The water barriers 4 may be arranged at uniform intervals, surrounding the microlens 11. The water barriers 4 may be formed of, for example, an organic precursor, which is hydrophobic, on the dielectric layer 5 by plasma enhanced convention vapor deposition (PECVD). The thickness of the water barrier 4 may be about 10 to 1500 Å.

The water barriers 4 may be formed of a hydrocarbon-based material such as naphthene-based hydrocarbon, aromatic hydrocarbon, polypropylene, polyethylene, ethylene-vinyl acetate or ethylene ethyl.

Alternatively, the water barriers 4 may be formed of a metal such as Ti, Cu or Pb on the dielectric layer 5 by electroplating or sputtering.

In addition, a metal such as Ti, Cu or Pb may be deposited on the water barrier 4 through the second open part 7b by electroplating or sputtering, thereby forming a barrier metal layer 13.

By thus forming the barrier metal layer 13, a crack and infiltration of water can be reduced or prevented.

Hereinafter, a method for manufacturing the CMOS image sensor will be explained in detail with reference to the accompanying drawings.

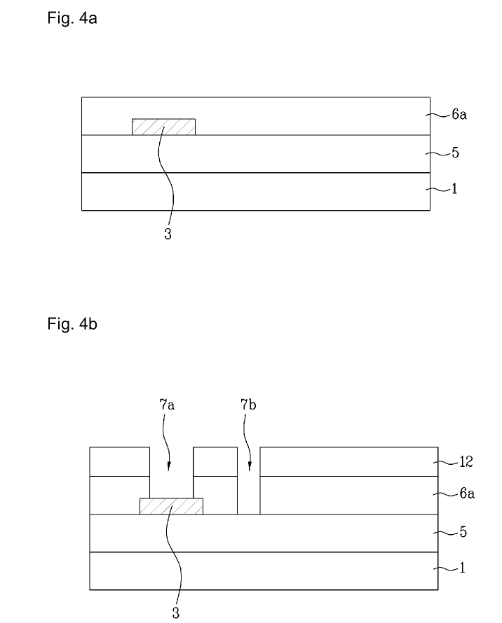

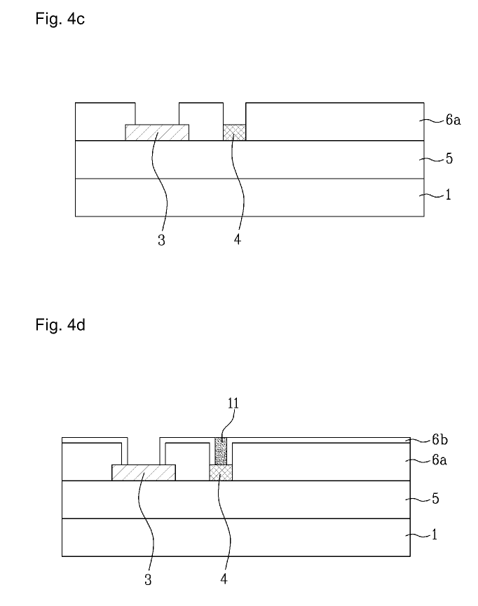

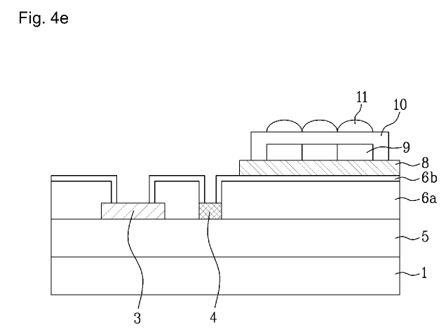

FIGS. 4A to 4E are process sectional views illustrating the image sensor manufacturing method.

Referring to FIG. 4A first, the dielectric layer 5 such as a gate dielectric layer or an interlayer dielectric is formed on the semiconductor substrate 1, and the metal pads 3 for each corresponding signal line are formed on the dielectric layer 5. The passivation layer 6a is formed on the whole surface of the dielectric layer 5 including the metal pads 3. The passivation layer may be made of, e.g., a nitride layer or an oxide layer.

Next, as shown in FIG. 4B, a photoconductive layer 12 is applied on the first passivation layer 6a, and etched through exposure and development so that an upper part of each metal pad 3 is exposed. The photoconductive layer 12 may also be etched so that a region for forming the water barrier 4 is also exposed. Additionally, the first passivation layer 6a is selectively etched using the etched photoconductive layer 12 as a mask. Thus, the first open part 7a is formed on the metal pad 3. Also, the second open part 7b is formed, which exposes the region corresponding to the water barrier 4.

As shown in FIG. 4C, the water barriers 4, being made of a hydrophobic organic precursor, may be formed through the second open part 7b by PECVD and arranged around the microlens 11 at uniform intervals. The water barriers 4 may have a thickness of about 10 to 1500 Å.

The water barriers 4 may be formed on the dielectric layer 5 by PECVD, using a hydrocarbon-based material including naphthene-based hydrocarbon, aromatic hydrocarbon, polypropylene, polyethylene, ethylene-vinyl acetate or ethylene ethyl. Alternatively, the water barriers 4 may be formed by depositing a metal including Ti, Cu and Pb on the dielectric layer 5 by electroplating or sputtering.

Next, as shown in FIG. 4D, the second passivation layer 6b may be formed by vapor-depositing a thermal resin (TR) or a thin TEOS on the whole surface of the semiconductor substrate 1, so as to protect the microlens 11 that will be manufactured in the following process. The second passivation layer 6b may be formed of, e.g., an LTO.

Before forming the planarization layer 8, the barrier metal layer 13 may be formed by depositing the metal such as Ti, Cu and Pb on the water barrier 4 through the second open part 7b by electroplating or sputtering.

As shown in FIG. 4E, the planarization layer 8 may be formed by vapor-depositing a silicon nitride layer or a silicon oxide nitride layer on the whole surface of the semiconductor substrate 1. The planarization layer 8 is selectively etched through a photo and etching process, thereby remaining only at parts not corresponding to the metal pad 3 and the barrier metal layer 13. In addition, the color filter layer 9 may be formed on the planarization layer 8 at positions corresponding to respective photodiode regions (not shown). The color filter layer 9 may be formed by applying a corresponding color resist and performing photolithography using dedicated masks.

Afterward, the overcoating layer 10 may be formed on the whole surface of the substrate 1, and then selectively etched by a photo and etching process to remain only at parts not corresponding to the metal pads 3 and the barrier metal layer 13.

Next, a polymer may be adhered to the overcoating layer 10 as the material for the microlens 11. A microlens area may be defined by patterning a photoconductive layer by exposure and development. The polymer may be selectively patterned using the photoconductive layer, thereby forming a microlens pattern corresponding to the color filter layer 9. Additionally, the microlens pattern may be thermally processed by a reflow process, thereby forming the microlens 11 of a hemispheric shape having a predetermined curvature.

As apparent from the above description, in accordance with the image sensor and a manufacturing method for the same according to the above-described embodiments, water barriers formed of a hydrophobic material are prepared between a microlens and metal pads. Accordingly, not only infiltration of water into the microlens but also generation of a crack during wire bonding can be prevented.

While the present invention has been described with respect to example embodiments, it will be apparent to those skilled in the art that various changes and modifications may be made without departing from the scope of the present invention as defined in the following claims.

What is claimed is:

1. A CMOS image sensor comprising:
a dielectric layer formed on a semiconductor substrate;
first and second passivation layers sequentially formed on the whole surface of the dielectric layer;
a planarization layer, a color filter layer, an overcoating layer and a microlens sequentially formed on the second passivation layer;
a plurality of metal pads arranged on the dielectric layer to surround the microlens;
a water barrier formed on the dielectric layer between the microlens and the metal pads; and
first and second open parts exposing the metal pads and the water barrier.

2. The CMOS image sensor according to claim 1, wherein the water barrier comprises a hydrocarbon-based material.

3. The CMOS image sensor according to claim 2, wherein the hydrocarbon-based material is selected from the group comprising: naphthene-based hydrocarbon, aromatic hydrocarbon, polypropylene, polyethylene, ethylene-vinyl acetate and ethylene ethyl.

4. The CMOS image sensor according to claim 1, wherein the water barrier has a thickness of about 10 to 1500 Å.

5. The CMOS image sensor according to claim 1, further comprising:
a barrier metal layer formed on the water barrier.

6. A method for manufacturing a CMOS image sensor, comprising:
forming a dielectric layer, a metal pad, and a first passivation layer sequentially on the whole surface of a semiconductor substrate;
forming first and second open parts by selectively etching the first passivation layer;
forming at least one water barrier on the dielectric layer through the second open part;
forming a second passivation layer on the whole surface of the first passivation layer; and
forming a planarization layer, a color filter layer, an overcoating layer, and a microlens sequentially on a microlens area formed on the second passivation layer.

7. The method according to claim 6, wherein the first open part is formed to expose the metal pad.

8. The method according to claim 6, wherein the second open part is formed between the first open part and the microlens.

9. The method according to claim 6, wherein the second passivation layer is formed using a low temperature oxide (LTO).

10. The method according to claim 6, wherein the at least one water barrier is formed of an organic precursor.

11. The method according to claim 6, wherein the at least one water barrier is formed by plasma enhanced convention vapor deposition (PECVD).

12. The method according to claim 6, wherein the at least one water barrier is formed of a hydrophobic material.

13. The method according to claim 6, wherein the at least one water barrier has a thickness of about 10 to 1500 Å.

14. The method according to claim 6, wherein the at least one water barrier comprises a hydrocarbon-based material.

15. The method according to claim 14, wherein the hydrocarbon-based material is selected from the group comprising: naphthene-based hydrocarbon, aromatic hydrocarbon, polypropylene, polyethylene, ethylene-vinyl acetate or ethylene ethyl

16. The method according to claim 6, wherein the at least one water barrier is formed by electroplating or sputtering a metal.

17. The method according to claim 16, wherein the water barrier metal is selected from the group comprising: Ti, Cu, and Pb

18. The method according to claim 6, further comprising:
forming a barrier metal layer on the at least one water barrier.

19. The method according to claim 18, wherein the barrier metal layer is formed in the second open part.

20. The method according to claim 6, wherein the at least one water barrier includes a plurality of water barriers arranged at uniform intervals around the microlens.
